(19) United States
(12) Patent Application Publication
(10) Pub. No.: US 2025/0153272 A1
(43) Pub. Date: May 15, 2025

(54) SUBSTRATE PROCESSING METHOD AND SUBSTRATE PROCESSING APPARATUS

(71) Applicant: Tokyo Electron Limited, Tokyo (JP)

(72) Inventor: Yohei YAMASHITA, Kikuchi-gun, Kumamoto (JP)

(73) Assignee: Tokyo Electron Limited, Tokyo (JP)

(21) Appl. No.: 18/833,922

(22) PCT Filed: Jan. 11, 2023
(86) PCT No.: PCT/JP2023/000388

§ 371 Date: Jul. 29, 2024

(30) Foreign Application Priority Data
Jan. 31, 2022 (JP) 2022-012808

(51) Int. Cl. B23K 26/0622; B23K 26/06; B23K 26/067; B23K 26/082; B23K 101/40; G02B 27/28; H01L 21/67

(52) U.S. Cl. CPC B23K 26/0622; B23K 26/0643; B23K 26/0648; B23K 26/067; B23K 26/082; G02B 27/283; H01L 21/67092; B23K 2101/40

(57) ABSTRACT

A substrate processing method of processing a substrate includes radiating multiple branch laser lights, which are obtained by branching laser light from a laser head, in a pulse shape in an outer peripheral region of the substrate; and radiating single laser light, which is obtained by not branching the laser light, in a pulse shape in a central region diametrically inside the outer peripheral region. A substrate processing apparatus configured to process the substrate includes a substrate holder configured to hold the substrate; a laser radiation device configured to radiate the laser light to the substrate held by the substrate holder; and a controller. The laser radiation device includes the laser head configured to oscillate the laser light; and an optical system configured to branch the laser light from the laser head.

### TECHNICAL FIELD

The various aspects and embodiments described herein pertain generally to a substrate processing method and a substrate processing apparatus.

### BACKGROUND

Patent Document 1 discloses a substrate processing method in which laser light is radiated in a pulse shape to a laser absorption layer of a combined substrate. In this substrate processing method, the laser light is radiated from an outer peripheral portion of the laser absorption layer toward a central portion thereof.

### PRIOR ART DOCUMENT

Patent Document 1: International Publication No. 2021/131711

### DISCLOSURE OF THE INVENTION

### Problems to be Solved by the Invention

Exemplary embodiments provide a technique enabling efficient radiation of laser light when processing a substrate by radiating the laser light to the substrate.

### Means For Solving the Problems

In an exemplary embodiment, a substrate processing method of processing a substrate includes radiating multiple branch laser lights, which are obtained by branching laser light from a laser head, in a pulse shape in an outer peripheral region of the substrate; and radiating single laser light, which is obtained by not branching the laser light, in a pulse shape in a central region diametrically inside the outer peripheral region.

### EFFECT OF THE INVENTION

According to the exemplary embodiment, it is possible to perform the radiation of the laser light efficiently when processing the substrate by radiating the laser light to the substrate.

### BRIEF DESCRIPTION OF THE DRAWINGS

FIG. 1 is a side view illustrating a schematic structure of a combined wafer processed in a wafer processing system.

FIG. 2 is a plan view schematically illustrating a configuration of the wafer processing system.

FIG. 3 is a side view illustrating a schematic configuration of a wafer processing apparatus.

FIG. 4 is a plan view illustrating the schematic configuration of the wafer processing apparatus.

FIG. 5 is an explanatory diagram illustrating a state in which laser light is radiated to a laser absorption layer.

FIG. 6A and FIG. 6B are explanatory diagrams illustrating a state in which a first wafer is separated from the laser absorption layer.

FIG. 7 is an explanatory diagram illustrating a state in which laser light is radiated to the laser absorption layer.

FIG. 8 is an explanatory diagram illustrating a state in which laser light is radiated to the laser absorption layer.

FIG. 9 is an explanatory diagram illustrating a schematic configuration of a laser radiation device according to a first exemplary embodiment.

FIG. 10 is an explanatory diagram illustrating the schematic configuration of a laser scanner.

FIG. 11A and FIG. 11B are explanatory diagrams illustrating a schematic configuration of a laser radiation device according to a second exemplary embodiment.

FIG. 12 is an explanatory diagram illustrating a schematic configuration of a laser radiation device according to a third exemplary embodiment.

FIG. 13 is an explanatory diagram illustrating a schematic configuration of a laser radiation device according to a fourth exemplary embodiment.

FIG. 14A and FIG. 14B are explanatory diagrams illustrating a schematic configuration of a spatial phase modulator.

FIG. 15 is an explanatory diagram illustrating a state in which laser light is radiated to a laser absorption layer according to another exemplary embodiment.

FIG. 16 is an explanatory diagram illustrating a state in which laser light is radiated to a laser absorption layer according to still another exemplary embodiment.

### DETAILED DESCRIPTION

In a manufacturing process for a semiconductor device, in a combined wafer in which two semiconductor substrates (hereinafter, simply referred to as “wafers”) are bonded, a device layer formed on a surface of a first wafer is transferred to a second wafer. This transfer of the device layer is performed by using, for example, laser lift-off. That is, laser light is radiated to a laser absorption layer formed between the first wafer and the device layer, and the first wafer and the laser absorption layer are separated so that the device layer is transferred to the second wafer.

In the laser lift-off, the laser light is radiated in a pulse shape while rotating the combined wafer and moving the laser light from an outer side to an inner side in a diametrical direction. At this time, in order to perform the separation of the first wafer and the laser absorption layer uniformly within the surface of the wafer, it is desirable to keep an interval at which the laser light is radiated, that is, a pulse interval constant. However, when it is attempted to maintain the pulse interval constant, the rotation speed of the combined wafer increases as the laser light moves from the outer side to the inner side in the diametrical direction. When the rotation speed of the combined wafer reaches an upper limit, the interval of the laser light decreases as the radiation position of the laser light is moved diametrically inwards, so the laser light may overlap at a central portion. Further, if the rotation speed of the combined wafer increases at the central portion, there is a risk that the first wafer may be separated.

Meanwhile, in order to improve throughput of a wafer processing, it has been proposed to diverge the laser light into multiple lights and radiate them simultaneously. If the plurality of laser lights are radiated simultaneously in this way, a processing time can be shortened at the outer peripheral portion, but at the central portion, the laser light may be radiated twice to the same location. Since there is a distance between the branched laser lights, when the laser lights are radiated to the central portion, the laser light radiated the first time and the laser light radiated the second time may overlap. In this case, more energy than necessary is supplied to the laser absorption layer, which may cause damage to the device layer due to heat generated. Also, the laser absorption layer may not be able to absorb all the laser lights, so the laser lights may reach the device layer, causing damage thereto.

The present disclosure provides a technique enabling the efficient radiation of the laser light when processing the substrate by radiating the laser light to the substrate. Hereinafter, a wafer processing system equipped with a wafer apparatus as a substrate processing apparatus and a wafer processing method as a substrate processing method according to an exemplary embodiment will be described with reference to the accompanying drawings. Further, in the present specification and the drawings, parts having substantially the same functions and configurations will be assigned same reference numerals, and redundant description thereof will be omitted.

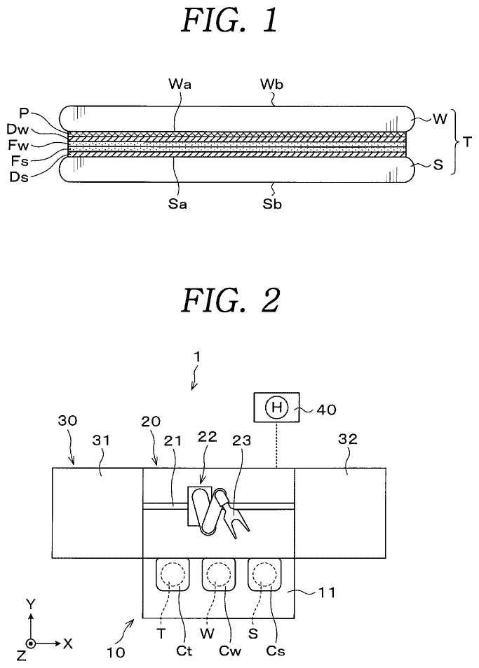

In a wafer processing system 1 to be described later according to an exemplary embodiment, a processing is performed on a combined wafer T as a substrate in which a first wafer W and a second wafer S are bonded, as shown in FIG. 1. Hereinafter, in the first wafer W, a surface bonded to the second wafer S will be referred to as a front surface Wa, and a surface opposite to the front surface Wa will be referred to as a rear surface Wb. Likewise, in the second wafer S, a surface bonded to the first wafer W will be referred to as a front surface Sa, and a surface opposite to the front surface Sa will be referred to as a rear surface Sb.

The first wafer W is a semiconductor wafer such as, but not limited to, a silicon substrate. On the front surface Wa of the first wafer W, a laser absorption layer P, a device layer Dw, and a surface film Fw are stacked in this order from the front surface Wa side. The laser absorption layer P absorbs laser light radiated from a laser radiation device 110, as will be described later. For the laser absorption layer P, an oxide film (SiO₂ film), for example, is used, but there is no particular limitation as long as it absorbs laser light. The device layer Dw includes a plurality of devices. The surface film Fw may be, by way of example, an oxide film (SiO₂ film or a TEOS film), a SiC film, a SiCN film, or an adhesive. Further, the position of the laser absorption layer P is not limited to the example of the above-described exemplary embodiment, and may be formed between the device layer Dw and the surface film Fw, for example. In addition, the device layer Dw and the surface film Fw may not be formed on the front surface Wa. In this case, the laser absorption layer P is formed on the second wafer S side, and a device layer Ds on the second wafer S to be described later is transferred to the first wafer W side.

The second wafer S is a semiconductor wafer such as, but not limited to, a silicon substrate. On the front surface Sa of the second wafer S, a device layer Ds and a surface film Fs are stacked in this order from the front surface Sa side. The device layer Ds and the surface film Fs are the same as the device layer Dw and the surface film Fw of the first wafer W, respectively. The surface film Fw of the first wafer W and the surface film Fs of the second wafer S are bonded. Further, the device layer Ds and the surface film Fs may not be formed on the front surface Sa.

As shown in FIG. 2, the wafer processing system 1 has a configuration in which a carry-in/out block 10, a transfer block 20 and a processing block 30 are connected as one body. The carry-in/out block 10 and the processing block 30 are provided around the transfer block 20. Specifically, the carry-in/out block 10 is disposed on the negative Y-axis side of the transfer block 20. A wafer processing apparatus 31 of the processing block 30 to be described later is disposed on the negative X-axis side of the transfer block 20, and a cleaning apparatus 32 to be described later is disposed on the positive X-axis side of the transfer block 20.

In the carry-in/out block 10, cassettes Ct, Cw, and Cs that can accommodate therein a plurality of combined wafers T, a plurality of first wafers W and a plurality of second wafers S, respectively, are carried to/from the outside, for example. The carry-in/out block 10 is provided with a cassette placement table 11. In the shown example, a plurality of, for example, the three cassettes Ct, Cw, and Cs can be arranged on the cassette placement table 11 in a row in the X-axis direction. Here, the number of the cassettes Ct, Cw, and Cs placed on the cassette placement table 11 is not limited to the example of the present exemplary embodiment but can be selected as required.

The transfer block 20 is provided with a wafer transfer device 22 configured to be movable on a transfer path 21 extending in the X-axis direction. The wafer transfer device 22 has, for example, two transfer arms 23 each configured to hold and transfer the combined wafer T, the first wafer W, or the second wafer S. Each transfer arm 23 is configured to be movable in a horizontal direction and a vertical direction and pivotable around a vertical axis. Further, the configuration of the transfer arm 23 is not limited to the present exemplary embodiment, and may have any of various configurations. In addition, the wafer transfer device 22 is configured to be able to transfer the combined wafer T, the first wafer W, and the second wafer S to/from the cassettes Ct, Cw, and Cs of the cassette placement table 11, the wafer processing apparatus 31 and the cleaning apparatus 32 to be described later.

The processing block 30 has the wafer processing apparatus 31 and the cleaning apparatus 32. The wafer processing apparatus 31 is configured to radiate laser light to the laser absorption layer P of the first wafer W to separate the first wafer W from the second wafer S. A detailed configuration of the wafer processing apparatus 31 will be described later.

The cleaning apparatus 32 is configured to clean a surface of the laser absorption layer P formed on the front surface Sa of the second wafer S separated in the wafer processing apparatus 31. For example, a brush is brought into contact with the surface of the laser absorption layer P, so that the corresponding surface is scrub-cleaned. Additionally, a pressurized cleaning liquid may be used to clean the surface. Furthermore, the cleaning apparatus 32 may be configured to clean the rear surface Sb of the second wafer S as well as the front surface Sa thereof.

The above-described wafer processing system 1 is equipped with a control device 40 as a controller. The control device 40 is, for example, a computer, and has a program storage (not shown). The program storage stores therein a program for controlling a processing of the combined wafer T in the wafer processing system 1. Furthermore, the program storage also stores therein a program for controlling operations of driving systems of the transfer devices and the various processing apparatuses described above to implement a wafer processing to be described later in the wafer processing system 1. In addition, the program may have been recorded on a computer-readable recording medium H, and may be installed from the recording medium H into the control device 40.

Now, the aforementioned wafer processing apparatus 31 will be discussed.

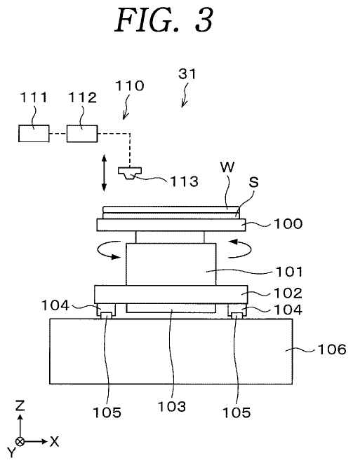

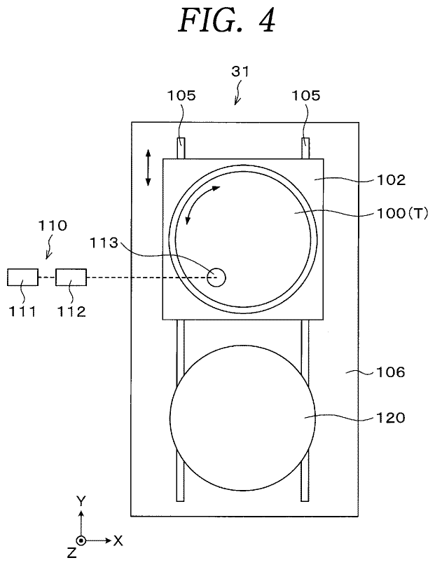

As depicted in FIG. 3 and FIG. 4, the wafer processing apparatus 31 has a chuck 100 as a substrate holder configured to hold the combined wafer T on a top surface thereof. The chuck 100 is configured to attract and hold the entire rear surface Sb of the second wafer S. Alternatively, the chuck 100 may be configured to attract and hold a part of the rear surface Sb. The chuck 100 is provided with an elevating pin (not shown) configured to move the combined wafer T up and down while supporting the combined wafer T from below. The elevating pin is configured to be movable up and down through a through hole (not shown) that is formed through the chuck 100.

The chuck 100 is supported on a slider table 102 with an air bearing 101 therebetween. A rotating mechanism 103 is provided at a bottom surface of the slider table 102. The rotating mechanism 103 has, for example, a motor embedded therein as a driving source. The chuck 100 is configured to be rotatable around a θ-axis (vertical axis) by the rotating mechanism 103 via the air bearing 101. The slider table 102 is configured to be movable along a rail 105, which is provided on a base 106 and extends in the Y-axis direction, by a moving mechanism 104 provided at the bottom surface thereof. Further, although not particularly limited, a driving source of the moving mechanism 104 may be, by way of non-limiting example, a linear motor.

The laser radiation device 110 is provided above the chuck 100. The laser radiation device 110 has a laser head 111, an optical system 112, and a lens 113. The lens 113 may be configured to be movable up and down by an elevating mechanism (not shown).

The laser head 111 has a laser oscillator (not shown) configured to oscillate laser light in a pulse shape. This laser light is a so-called pulse laser. Further, in the present exemplary embodiment, the laser light is CO₂ laser light, which has a wavelength of, e.g., 8.9 μm to 11 μm. Further, the laser head 111 may have other devices besides the laser oscillator, such as an amplifier.

The optical system 112 has an optical element (not shown) configured to control the intensity and the position of the laser light, and an attenuator (not shown) configured to attenuate the laser light to adjust an output thereof. Furthermore, the optical system 112 serves to control branching of the laser light. A configuration of controlling the branching of the laser light will be described later.

The lens 113 is configured to radiate the laser light to the combined wafer T held by the chuck 100. The laser light emitted from the laser radiation device 110 penetrates the first wafer W to be radiated to the laser absorption layer P.

Furthermore, a transfer pad 120 is provided above the chuck 100. The transfer pad 120 is configured to be movable up and down by an elevating mechanism (not shown). Further, the transfer pad 120 has an attraction surface for the first wafer W. The transfer pad 120 serves to transfer the first wafer W between the chuck 100 and the transfer arm 23. Specifically, after the chuck 100 is moved to below the transfer pad 120 (to a delivery position with respect to the transfer arm 23), the transfer pad 120 attracts and holds the rear surface Wb of the first wafer W, and separates it from the second wafer S. Subsequently, the separated first wafer W is handed over to the transfer arm 23 from the transfer pad 120, and carried out from the wafer processing apparatus 31.

Next, a wafer processing performed by using the wafer processing system 1 configured as described above will be discussed. In the present exemplary embodiment, the first wafer W and the second wafer S are bonded in a bonding apparatus (not shown) outside the wafer processing system 1 to form the combined wafer T in advance.

First, the cassette Ct accommodating therein the plurality of combined wafers T is placed on the cassette placement table 11 of the carry-in/out block 10.

Then, the combined wafer T in the cassette Ct is taken out by the wafer transfer device 22 and transferred to the wafer processing apparatus 31. In the wafer processing apparatus 31, the combined wafer T is transferred from the transfer arm 23 to the chuck 100 to be attracted to and held by the chuck 100. Subsequently, the chuck 100 is moved to a processing position by the moving mechanism 104. This processing position is a position where the laser light can be radiated to the combined wafer T (laser absorption layer P) from the laser radiation device 110.

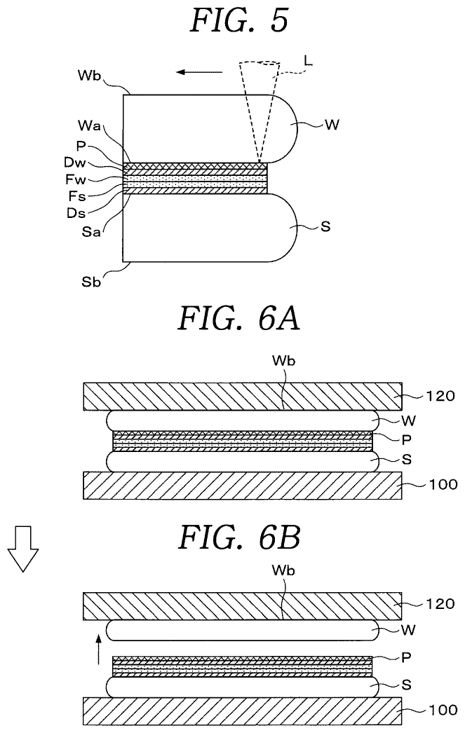

Next, as shown in FIG. 5, laser light L (CO₂ laser light) is radiated in a pulse shape from the laser radiation device 110 to the laser absorption layer P, more specifically, to an interface between the laser absorption layer P and the first wafer W. At this time, the laser light L passes through the first wafer W from the rear surface Wb side of the first wafer W and is absorbed into the laser absorption layer P. This laser light L causes the separation at the interface between the laser absorption layer P and the first wafer W. A specific method of radiating this laser light L will be described later.

In this way, the laser light L is radiated to the laser absorption layer P in the pulse shape. When the laser light L is oscillated in the pulse shape, a peak power (maximum intensity of the laser light) may be set to be high to cause the separation at the interface between the laser absorption layer P and the first wafer W. As a result, the first wafer W can be appropriately separated from the laser absorption layer P.

Next, the chuck 100 is moved to the delivery position by the moving mechanism 104. Then, as shown in FIG. 6A, the rear surface Wb of the first wafer W is attracted to and held by the transfer pad 120. Afterwards, as shown in FIG. 6B, with the first wafer W attracted to and held by the transfer pad 120, the transfer pad 120 is raised to separate the first wafer W from the laser absorption layer P. At this time, as the separation has occurred at the interface between the laser absorption layer P and the first wafer W due to the radiation of the laser light L as described above, the first wafer W can be separated from the laser absorption layer P without applying a great load. Alternatively, the first wafer W may be separated by rotating the transfer pad 120 around a vertical axis.

The separated first wafer W is transferred from the transfer pad 120 to the transfer arm 23 of the wafer transfer device 22 and transferred to the cassette Cw of the cassette placement table 11. Further, the first wafer W carried out from the wafer processing apparatus 31 may be transferred to the cleaning apparatus 32 before being transferred to the cassette Cw, and its front surface Wa, which is a separation surface, may be cleaned. In this case, the front and rear surfaces of the first wafer W may be inverted by the transfer pad 120 before being transferred to the transfer arm 23.

Meanwhile, the second wafer S held by the chuck 100 is handed over to the transfer arm 23 and transferred to the cleaning apparatus 32. In the cleaning apparatus 32, the surface of the laser absorption layer P, which is a separation surface, is scrub-cleaned. Furthermore, in the cleaning apparatus 32, the rear surface Sb of the second wafer S as well as the surface of the laser absorption layer P may be cleaned. Alternatively, cleaning devices configured to respectively clean the surface of the laser absorption layer P and the rear surface Sb of the second wafer S may be provided individually.

Afterwards, the second wafer S after being subjected to all the required processes is transferred to the cassette Cs of the cassette placement table 11 by the wafer transfer device 22. In this way, the series of processes of the wafer processing in the wafer processing system 1 are completed.

Now, a method of radiating the laser light L in the wafer processing apparatus 31 described above will be described. Further, as will be described later, the laser radiation device 110 can branch the laser light L and scan the laser light L. In the following description, scanning the laser light L means moving the laser light L radiated from the lens 113 of the laser radiation device 110 with respect to the laser absorption layer P.

In the present exemplary embodiment, while rotating the combined wafer T and moving the laser light L from a diametrically outer side toward a diametrically inner side, the laser light L is radiated in a pulse shape. At this time, if it is attempted to keep the interval of the radiation of the laser light L constant in order to perform the separation of the first wafer W and the laser absorption layer P uniformly within the wafer surface, the rotation speed of the combined wafer T is accelerated as the laser light L is moved from the diametrically outer side toward the diametrically inner side. In such a case, the laser light L may overlap at a central region of the laser absorption layer P, and if the rotation speed of the combined wafer T increases at the central region, there is a risk that the first wafer W being rotated may be separated during the processing. Therefore, the laser light L is radiated at an outer peripheral region while rotating the combined wafer T, whereas the laser light L is scanned at the central region while the rotation of the combined wafer T is stopped.

In addition, in the present exemplary embodiment, in order to improve the throughput of the wafer processing, the laser light L is branched into multiple lights, which are radiated at the same time. In this way, if the multiple laser lights L are radiated at the same time, a processing time can be shortened at the outer peripheral region. At the central region, however, the laser light may be radiated twice to the same position. There is a distance between the branched laser lights L. Therefore, when the laser light L is scanned at the central region, the laser light L radiated the first time and the laser light L radiated the second time may overlap. In this case, since the laser absorption layer P is supplied with more energy than necessary, there is a risk that the device layer Dw may be damaged by heat generated. Further, there is also a risk that the laser light L may not be completely absorbed by the laser absorption layer P but reach the device layer Dw, causing damage thereto. Therefore, in order to avoid the influence of the distance between the branched laser lights L, the laser light L is radiated to the central region without being branched.

As described above, in the present exemplary embodiment, the radiation method (optical system 112) of the laser light L is switched in the outer peripheral region and the central region of the laser absorption layer P. Further, a boundary between the outer peripheral region and the central region is, for example, a position where the rotational speed of the chuck 100 reaches the upper limit, for example, a limit position where branch laser lights L1 and L2 to be described later, which are branched from the laser light L, do not overlap when the chuck 100 is moved from the diametrically outer side toward the diametrically inner side.

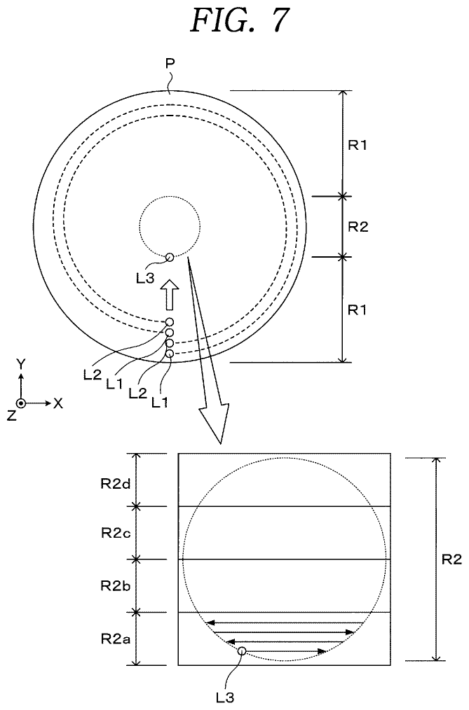

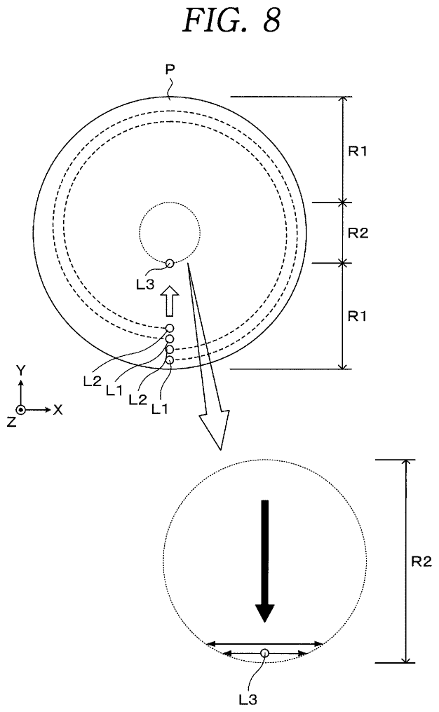

As shown in FIG. 7 and FIG. 8, at an outer peripheral region R1 of the laser absorption layer P, the chuck 100 (combined wafer T) is rotated by the rotating mechanism 103, and, also, the chuck 100 is moved in the negative Y-axis direction by the moving mechanism 104. At this time, the laser light L from the laser head 111 is branched into multiple laser lights, for example, into two laser lights in the laser radiation device 110, and the branched laser lights (hereinafter referred to as “branch laser light”) L1 and L2 are radiated simultaneously in a pulse shape. Further, the branch laser lights L1 and L2 are fixedly radiated without being scanned. As a result, at the outer peripheral region R1, two rows of branch laser lights L1 and L2 are radiated in a spiral shape from the diametrically outer side toward the diametrically inner side.

In addition, the number of the branch laser lights L1 and L2 is not limited to the present exemplary embodiment, and may be more than two, for example.

Furthermore, an interval (index pitch) between the branch laser lights L1 and L2 in the diametrical direction is adjusted in the laser radiation device 110 as will be described later. Further, at the outer peripheral region R1, the interval between the branch laser lights L1 and L2 in the diametrical direction is adjusted such that the branch laser lights L1 and L2 are radiated to a range where they are not affected by each other.

At the central region R2 of the laser absorption layer P, the rotation of the chuck 100 is stopped. Then, in the laser radiation device 110, the laser light L from the laser head 111 is not branched, and this unbranched laser light (hereinafter referred to as “single laser light”) L3 is radiated in a pulse shape. Further, this single laser light L3 is scanned at the central region R2.

At this time, as shown in FIG. 7, the scanning radiation of the single laser light L3 and the movement of the chuck 100 in the negative Y-axis direction may be repeated at the central region R2. The scanning range of the single laser light L3 in one scan is limited by the performance of a laser scanner. For example, if the scanning range is smaller than the central region R2, the scanning of the single laser light L3 is repeated. In the shown example, the central region R2 is divided into four scanning regions R2a to R2d. After radiating the single laser light L3 to the scanning region R2a while scanning the laser light L3, the chuck 100 is moved in the negative Y-axis direction, and, subsequently, the single laser light L3 is radiated to the scanning region R2b while being scanned. By repeating this scanning radiation of the single laser light L3 and the movement of the chuck 100 in the negative Y-axis direction, the singe laser light L3 is radiated to the entire central region R2.

In addition, at the central region R2, the scanning radiation of the single laser light L3 and the movement of the chuck 100 in the negative Y-axis direction may be synchronized, as shown in FIG. 8. By moving the chuck 100 in the negative Y-axis direction (indicated by a black arrow in FIG. 8) while radiating and scanning the single laser light L3 in this manner, the entire central region R2 is irradiated with the single laser light L3.

Moreover, the two rows of branch laser lights L1 and L2 are radiated in the spiral shape in the present exemplary embodiment. For this reason, when switching from the branch laser lights L1 and L2 to the single laser light L3, a very small unirradiated portion to which no laser light is radiated may exist at a boundary between the outer peripheral region R1 and the central region R2 from a position where the radiation of the branch laser lights L1 and L2 is stopped. Thus, although not shown in detail in FIG. 7 and FIG. 8, the single laser light L3 is radiated at an appropriate index pitch so as to fill in the unirradiated portion, so that the single laser light L3 is radiated to this unirradiated portion as well.

According to the present exemplary embodiment, at the outer peripheral region R1, since the multiple branch laser lights L1 and L2 are simultaneously radiated multifocally, the throughput of the wafer processing can be improved. Further, at the central region R2, since the single laser light L3 is radiated monofocally, it is possible to suppress the single laser light L3 from being radiated twice to the same location, so that the damage to the device layer Dw can be suppressed.

Further, although the branch laser lights L1 and L2 are radiated in the spiral shape at the outer peripheral region R1 in the present exemplary embodiment, it may be radiated concentrically or annularly. In addition, although the chuck 100 is rotated when radiating the branch laser lights L1 and L2 at the outer peripheral region R1 in the present exemplary embodiment, the lens 113 may be moved to be rotated relative to the chuck 100. Furthermore, although the chuck 100 is moved in the Y-axis direction, the lens 113 may be moved in the Y-axis direction.

In addition, in the present exemplary embodiment, although the laser light L (branch laser lights L1 and L2 and the single laser light L3) is radiated from the diametrically outer side toward the diametrically inner side in the laser absorption layer P, it may be radiated from the diametrically inner side toward the diametrically outer side.

Now, several exemplary embodiments regarding a configuration of the laser radiation device 110 configured to perform the above-described radiation method of the laser light L will be described. In any of the various exemplary embodiments, the laser radiation device 110 controls the branching of the laser light L from the laser head 111, and also controls the scanning of the laser light L.

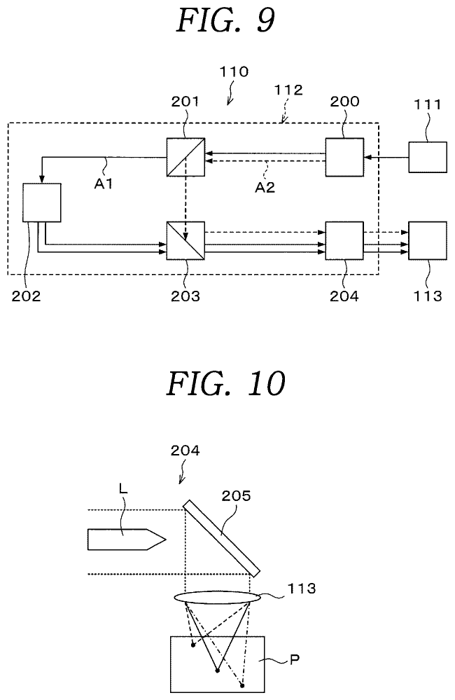

As depicted in FIG. 9, in the laser radiation device 110 of a first exemplary embodiment, the optical system 112 has a polarization adjuster 200, a polarization separator 201, a branch generator 202, a polarization synthesizer 203, and a laser scanner 204. The polarization adjuster 200, the polarization separator 201, the branch generator 202, the polarization synthesizer 203, and the laser scanner 204 are arranged in this order on an optical path of the laser light L in the optical system 112.

The polarization adjuster 200 is configured to adjust polarization of the laser light L from the laser head 111. The polarization adjuster 200 emits P-polarized light and S-polarized light separately in a luminous flux of the laser light L. In other words, the polarization adjuster 200 performs a switchover between the P-polarized light (corresponding to the branch laser lights L1 and L2 as will be described below) and the S-polarized light (corresponding to the single laser light L3 as will be described below). The P-polarized light is linearly polarized light in which an electric field oscillates within a incidence plane, and the S-polarized light is linearly polarized light in which an electric field oscillates perpendicular to the incidence plane.

The polarization separator 201 is configured to transmit or reflect the polarized light adjusted by the polarization adjuster 200. When the P-polarized light is emitted from the polarization adjuster 200, the polarization separator 201 transmits the P-polarized light and directs it to the branch generator 202. Meanwhile, when the S-polarized light is emitted from the polarization adjuster 200, the polarization separator 201 reflects the S-polarized light and directs it to the polarization synthesizer 203.

The branch generator 202 is configured to branch the P-polarized light transmitted through the polarization separator 201 into a plurality of lights, for example, two lights. The branch generator 202 is equipped with an optical element (not shown), and is capable of adjust an interval (index pitch) of the two P-polarized lights in the diametrical direction as required by rotating the optical element. Specifically, the interval of the two P-polarized lights in the diametrical direction is adjusted such that the two P-polarized lights are radiated to a range where they are not affected by each other.

In addition, although the configuration of the branch generator 202 is not particularly limited, diffractive optical elements (DOE) may be used, for example. Further, the number of the branches of the P-polarized light in the branch generator 202 is not limited to the present exemplary embodiment, and may be more than two, for example.

The polarization synthesizer 203 is configured to reflect the S-polarized light reflected from the polarization separator 201 and directs it to the laser scanner 204. In addition, the polarization synthesizer 203 transmits the plurality of P-polarized lights branched from the branch generator 202 and directs them to the laser scanner 204.

The laser scanner 204 is configured to control the scanning of the polarized light (laser light L), and galvano, for example, is used. As shown in FIG. 10, a plurality of galvano mirrors 205 are disposed inside the laser scanner 204. Further, an f-θ lens is used as the lens 113. With this configuration, the polarized light inputted to the laser scanner 204 is reflected by the galvano mirror 205, propagated to the lens 113, and radiated to the laser absorption layer P. Here, by adjusting the angle of the galvano mirror 205, the polarized light can be scanned with respect to the laser absorption layer P.

In the optical system 112, a first optical path A1 and a second optical path A2 are formed.

The first optical path A1 is an optical path that branches the P-polarized light of the laser light L. That is, in the first optical path A1, the P-polarized light is transmitted through the polarization separator 201, branched by the branch generator 202, and transmitted through the polarization synthesizer 203. Further, the P-polarized light branched through the first optical path A1 passes through the laser scanner 204, but is not scanned with respect to the laser absorption layer P.

The outer peripheral region R1 of the laser absorption layer P is irradiated with two branched P-polarized lights having passed through the first optical path A1. These two P-polarized lights correspond to the aforementioned branch laser lights L1 and L2.

The second optical path A2 is an optical path that does not branch the S-polarized light of the laser light L. That is, in the second optical path A2, the S-polarized light is reflected by the polarization separator 201 and reflected by the polarization synthesizer 203. Further, the S-polarized light having passed through the second optical path A2 passes through the laser scanner 204 and is scanned with respect to the laser absorption layer P.

The S-polarized light is radiated to the central region R2 of the laser absorption layer P through the second optical path A2 while being scanned. This S-polarized light corresponds to the aforementioned laser light L3.

In the present exemplary embodiment, the P-polarized light of the laser light L is branched into the laser lights L1 and L2, and the S-polarized light is set as the single laser light L3. However, the S-polarized light may be branched, whereas the P-polarized light may not be branched. In other words, the S-polairzed light may pass through the first optical path A1, and the P-polarized light may pass through the second optical path A2.

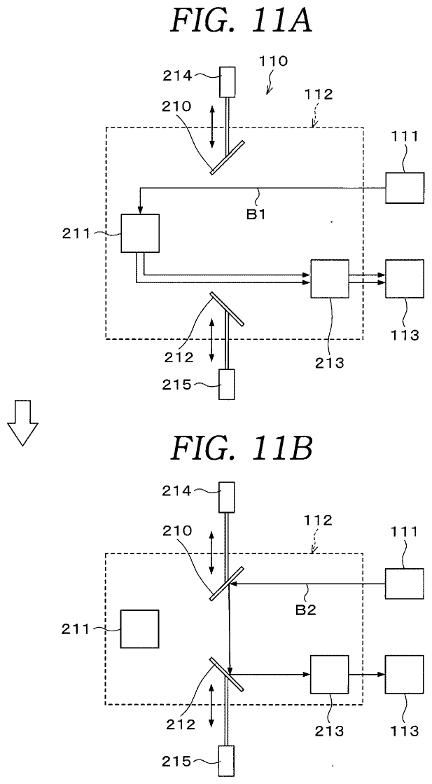

Referring to FIG. 11A and FIG. 11B, in the laser radiation device 110 of a second exemplary embodiment, the optical system 112 has a first mirror 210, a branch generator 211, a second mirror 212, and a laser scanner 213. The first mirror 210, the branch generator 211, the second mirror 212, and the laser scanner 213 may be arranged in this order on the optical path of the laser light L in the optical system 112.

The branch generator 211 is configured to branch the laser light L into a plurality of laser lights, for example, two laser lights. Here, the number of the branches of the laser light L in the branch generator 211 is not limited to the present exemplary embodiment, and may be more than two, for example. A configuration of this branch generator 211 is the same as the configuration of the branch generator 202 of the first exemplary embodiment.

The laser scanner 213 is configured to control scanning of the laser light L, and galvano, for example, is used. A configuration of the laser scanner 213 is the same as the configuration of the laser scanner 204 of the first exemplary embodiment.

The first mirror 210 and the second mirror 212 are configured to be movable with respect to the optical path by moving mechanisms 214 and 215, respectively. The first mirror 210 disposed in the optical path reflects the laser light L from the laser head 111 to direct it to the second mirror 212. Further, the second mirror 212 disposed in the optical path reflects the laser light L to direct it toward the laser scanner 204.

As illustrated in FIG. 11A, when the first mirror 210 and the second mirror 212 are retreated from the optical path, a first optical path B1 is formed. The first optical path B1 is an optical path that branches the laser light. That is, in the first optical path B1, the laser light L from the laser head 111 is branched by the branch generator 211. The laser light L branched through the first optical path B1 then passes through the laser scanner 213, but is not scanned with respect to the laser absorption layer P.

The outer peripheral region R1 of the laser absorption layer P is irradiated with two laser lights branched through the first optical path B1. These two laser lights L correspond to the aforementioned branch laser lights L1 and L2.

As shown in FIG. 11B, when the first mirror 210 and the second mirror 212 are advanced into the optical path and disposed therein, a second optical path B2 is formed. The second optical path B2 is an optical path that does not branch the laser light L. In other words, in the second optical path B2, the laser light L from the laser head 111 is reflected by the first mirror 210 and also reflected by the second mirror 212. The laser light L having passed through the second optical path B2 then passes through the laser scanner 213 and is scanned with respect to the laser absorption layer P.

The laser light L having passed through the second optical path B2 is radiated to the central region R2 of the laser absorption layer P while being scanned. This laser light L corresponds to the aforementioned single laser light L3.

In addition, in the present exemplary embodiment, the first mirror 210 and the second mirror 212 are respectively configured to be movable forward and backward. However, the configuration of forming the first optical path B1 and the second optical path B2 is not limited thereto. For example, each of the first mirror 210 and the second mirror 212 may be configured to be switched to reflect or transmit the laser light by using, for example, an electric voltage. Alternatively, the first mirror 210 and the second mirror 212 may be omitted, and the branch generator 211 may be configured to be movable with respect to the optical path.

According to the above-described first and second exemplary embodiments, as the optical system 112 has the first optical path A1 (B1) and the second optical path A2 (B2), the branching of the laser light L can be controlled. Further, the scanning of the laser light L can be controlled by, for example, the galvano as the laser scanner 204 (213). Thus, the throughput of the wafer processing can be improved, and the single laser light L3 can be suppressed from being radiated twice to the same location.

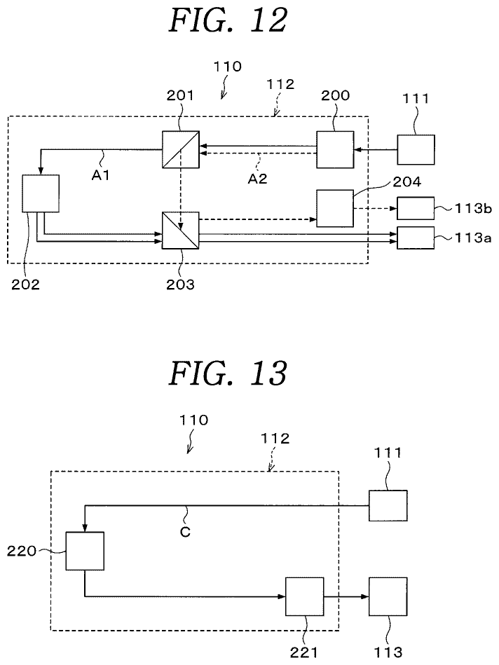

As depicted in FIG. 12, in the laser radiation device 110 of a third exemplary embodiment, the lens 113 includes a fixed lens 113a and a scanning lens 113b. In the laser radiation devices 110 of the first and second exemplary embodiments, the optical system 112 has two optical paths and radiates the laser light L from the single lens 113. Meanwhile, in the laser radiation device 110 of the third exemplary embodiment, the optical system 112 has two optical paths and radiates the laser light L from the lenses 113a and 113b respectively corresponding to the two optical paths. In addition, although the following description will be provided for a case where the optical system 112 of the third exemplary embodiment is the optical system 112 of the first exemplary embodiment, it may be the optical system 112 of the second exemplary embodiment.

The fixed lens 113a is provided in correspondence to the first optical path A1. The fixed lens 113a radiates the P-polarized light to a predetermined location without scanning it. The P-polarized light (branch laser lights L1 and L2) branched through the first optical path A1 is radiated to the outer peripheral region R1 of the laser absorption layer P via the fixed lens 113a without being scanned. At this time, the chuck 100 is rotated, and is also moved in the negative Y-axis direction.

The scanning lens 113b is provided in correspondence to the second optical path A2. An f-θ lens is used as the scanning lens 113b, and the S-polarized light is scanned by the laser scanner 204. The S-polarized light (single laser light L3) having passed through the second optical path A2 is radiated to the central region R2 of the laser absorption layer P via the scanning lens 113b while being scanned.

In addition, in the third exemplary embodiment, the laser scanner 204 is not provided in the first optical path A1, but is provided in the second optical path A2.

According to the above-described third exemplary embodiment, the same effects as the first and second exemplary embodiments can be achieved. That is, the branching of the laser light L is controlled by the two optical paths A1 and A2, and the scanning of the laser light L is also controlled by, for example, the galvano as the laser scanner 204. Thus, the throughput of the wafer processing can be improved, and the single laser light L3 can be suppressed from being radiated twice to the same location.

Here, when radiating the P-polarized light (branch laser lights L1 and L2) to the outer peripheral region R1 of the laser absorption layer P, the P-polarized light is fixedly radiated without being scanned. In this case, if the operation of the laser scanner 204 is stopped for a long time, the lens 113 corresponding to this laser scanner 204 may be damaged. In the present exemplary embodiment, however, as the laser scanner 204 is not provided but the fixed lens 113a different from the scanning lens 113b is provided in the first optical path A1, the P-polarized light does not pass through the fixed lens 113a, so that the fixed lens 113a can be suppressed from suffering the damage.

As shown in FIG. 13, in the laser radiation device 110 of a fourth exemplary embodiment, the optical system 112 has a spatial phase modulator 220 and a laser scanner 221. The spatial phase modulator 220 and the laser scanner 221 are arranged in this order on an optical path C of the laser light L in the optical system 112.

The laser scanner 221 is configured to control scanning of the laser light L, and, for example, galvano is used. A configuration of the laser scanner 221 is identical to that of the laser scanner 204 of the first exemplary embodiment.

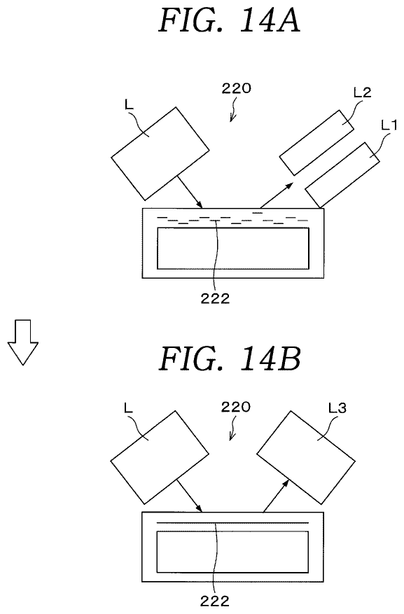

The spatial phase modulator 220 is configured to control the phase of the laser light L to control the branching of the laser light L. For the spatial phase modulator 220, a deformable mirror, for example, is used. As shown in FIG. 14A and FIG. 14B, a plurality of mirrors 222 are disposed inside the spatial phase modulator 220. By individually controlling up and down movements of the plurality of mirrors 222 in a programmable manner, the branching of the laser light L is controlled.

If the up and down placements of the plurality mirrors 222 are controlled as shown in FIG. 14A, the inputted laser light L branches, so the branch laser lights L1 and L2 are outputted. These branch laser lights L1 and L2 are radiated to the outer peripheral region R1 of the laser absorption layer P as described above.

If the arrangement of the plurality of mirrors 222 is controlled to be flat as shown in FIG. 14B, the inputted laser light L is not diverged, and the single laser light L3 is outputted. This single laser light L3 is radiated in the central region R2 of the laser absorption layer P as stated above.

In addition, in the present exemplary embodiment, although the deformable mirror is used as the spatial phase modulator 220, the configuration of the spatial phase modulator 220 is not limited thereto. For example, a liquid crystal silicon (LCOS) may be used as the spatial phase modulator 220. The LCOS is capable of controlling the focus position and the phase of the laser light L, and is thus capable of controlling the shape and the number of branches of the laser light L.

According to the above-described fourth exemplary embodiment, the optical path C in the optical system 112 is only one, unlike in the first to third exemplary embodiments. However, the branching of the laser light L can still be controlled by the spatial phase modulator 220. Furthermore, the scanning of the laser light L can be controlled by, for example, the galvano as the laser scanner 221. Therefore, the throughput of the wafer processing can be improved, and, also, the single laser light L3 can be suppressed from being radiated twice to the same location.

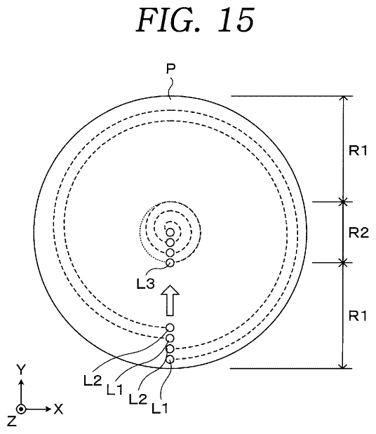

In the above-described exemplary embodiments, the single laser light L3 is radiated to the central region R2 of the laser absorption layer P while being scanned in the state that the rotation of the chuck 100 (combined wafer T) is stopped. As shown in FIG. 15, however, the single laser light L3 may be radiated while being scanned, while rotating the combined wafer T.

For example, in the above-described exemplary embodiments, in order to avoid the overlap of the laser light L at the central region R2 due to the rotation speed of the combined wafer T and to avoid the separation of the first wafer W being rotated during the processing, the rotation of the combined wafer T is stopped at the central region R2. If there is no risk of the overlap of the laser light L and the separation of the first wafer W at the central region R2, it is not necessary to stop the rotation of the combined wafer T at the central region R2. In this case, the rotation speed of the combined wafer T at the central region R2 may be set to be lower than the rotation speed at the outer peripheral region R1.

Furthermore, the same as in the exemplary embodiment shown in FIG. 7 and FIG. 8, when switching from the branch laser lights L1 and L2 to the single laser light L3 at the boundary between the outer peripheral region R1 and the central region R2, the single laser light L3 is radiated at an appropriate index pitch such that it is continuous to the radiation points of the branch laser lights L1 and L2.

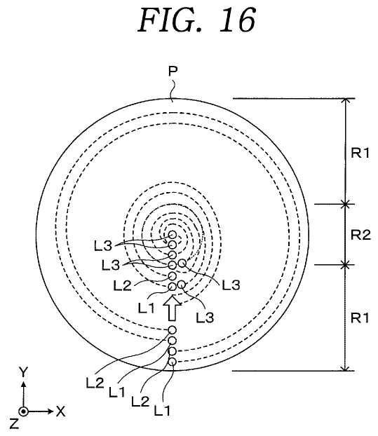

In addition, as illustrated in FIG. 16, the laser light L3 may be scanned by being rotated while the rotation of the combined wafer T is stopped. Specifically, the galvano mirror 205 as the laser scanner 204 (213, 221), for example, scans the single laser light L3 by rotating it with a rotating mechanism (not shown).

At this time, the same as in the above-described exemplary embodiments shown in FIG. 7, FIG. 8 and FIG. 15, when switching from the branch laser lights L1 and L2 to the single laser light L3 at the boundary between the outer peripheral region R1 and the central region R2, the single laser light L3 is radiated at the appropriate index pitch such that it is continuous to the radiation points of the branch laser lights L1 and L2. Further, when switching from the branch laser lights L1 and L2 to the single laser light L3, a small unirradiated portion to which no laser light is radiated may be formed from the position where the radiation of the branch laser lights L1 and L2 is stopped. The single laser light L3 is radiated to fill in this unirradiated portion. In this case, the single laser light L3 may not be continuous from the radiation point of the branch laser light L1 or the branch laser light L2.

Although the branch laser lights L1 and L2 are radiated in the spiral shape at the outer peripheral region R1 in the exemplary embodiments shown in FIG. 15 and FIG. 16, they may be radiated concentrically or annularly. In addition, although the single laser light L3 is also radiated in the spiral shape at the central region R2, it may be radiated concentrically or annularly.

In the above-described exemplary embodiments, the galvano is used as the laser scanners 204, 213, and 221 configured to scan the single laser light L3. However, the configuration of scanning the single laser light L3 is not limited thereto as long as the radiation point of the laser light radiated from the lens can be scanned or rotated in a direction opposed to the Y-axis direction, for example. As a specific example, a lens may scan the laser light by a scanning mechanism or a rotating mechanism.

In the above-described exemplary embodiments, the method of radiating the laser light L is switched in the outer peripheral region R1 and the central region R2 of the laser absorption layer P (laser radiation target). However, the switching method is not limited thereto. The radiation range of the branch laser lights L1 and L2 and the radiation range of the unbranched single laser light L3 may be set as required.

In the above-described exemplary embodiments, the method of radiating the laser light L according to the present disclosure is applied when performing the laser lift-off to separate the first wafer W from the laser absorption layer P. However, the wafer processing to which the present method is applicable is not limited thereto.

In a manufacturing process for a semiconductor device, by radiating laser light to an inside of a silicon substrate of a wafer, which has a plurality of devices such as electronic circuits formed on a surface thereof, along a plane direction, a modification layer is formed, and the wafer is thinned by being separated starting from this modification layer. For this laser light, YAG laser light is used. The laser light radiation method according to the present disclosure can also be applied when forming the modification layer in this way. In addition, the laser light radiation method of the present disclosure can also be applied to a technology of surface modification and surface flattening of the wafer.

It should be noted that the above-described exemplary embodiment is illustrative in all aspects and is not anyway limiting. The above-described exemplary embodiment may be omitted, replaced and modified in various ways without departing from the scope and the spirit of claims.

### EXPLANATION OF CODES

31: Wafer processing apparatus
40: Control device
100: Chuck
110: Laser radiation device
111: Laser head
112: Optical system
T: combined wafer
W: first wafer
S: Second wafer

1. A substrate processing method, comprising:
radiating multiple branch laser lights, which are obtained by branching laser light from a laser head, in a pulse shape to an outer peripheral region of a substrate; and
radiating single laser light, which is obtained by not branching the laser light, in a pulse shape to a central region diametrically inside the outer peripheral region.

2. The substrate processing method of claim 1,
wherein the radiating the multiple branch laser lights includes radiating, to the outer peripheral region, the multiple branch laser lights while rotating the substrate, and
the radiating the single laser light includes radiating, to the central region, the single laser light while being scanned in a state where rotation of the substrate is stopped.

3. The substrate processing method of claim 2,
wherein the multiple branch laser lights are radiated from a fixed lens, and
the single laser light is radiated from a scanning lens.

4. The substrate processing method of claim 1,
wherein the multiple branch laser lights are branched by an optical system, the optical system including:
a first optical path in which the laser light is branched; and
a second optical path in which the laser light is not branched,
in the outer peripheral region, the optical system passes the laser light through the first optical path to radiate the multiple branch laser lights, and
in the central region, the optical system passes the laser light through the second optical path to radiate the single laser light.

5. The substrate processing method of claim 4,
wherein the optical system further comprises:
a polarization adjuster configured to adjust polarization of the laser light:
a polarization separator configured to transmit or reflect polarized light adjusted by the polarization adjuster:
a branch generator configured to branch the polarized light transmitted by the polarization separator: and
a polarization synthesizer configured to reflect the polarized light reflected by the polarization separator or transmit the polarized light branched by the branch generator,
in the first optical path, the polarized light is transmitted by the polarization separator, branched by the branch generator, and transmitted by the polarization synthesizer, and
in the second optical path, the polarized light is reflected by the polarization separator and reflected by the polarization synthesizer.

6. The substrate processing method of claim 4,
wherein the optical system further comprises:
a branch generator configured to branch the laser light:
a first mirror configured to be moved forward and backward and positioned at an upstream side of the branch generator; and
a second mirror configured to be moved forward and backward and positioned at a downstream side of the branch generator,
in the first optical path, the laser light is branched by the branch generator in a state that the first mirror and the second mirror are in a retreated position and the laser light is not reflected from the first mirror and the second mirror, and
in the second optical path, the laser light is reflected by the first mirror and reflected by the second mirror in a state that the first mirror and the second mirror are in an advanced position.

7. The substrate processing method of claim 1,
wherein an optical system configured to control the branching of the laser light comprises a spatial phase modulator of the laser light, and
by controlling a phase of the laser light in the spatial phase modulator, the branching of the laser light is controlled.

8. A substrate processing apparatus, comprising:
a substrate holder configured to hold a substrate;
a laser radiation device configured to radiate laser light to the substrate held by the substrate holder; and
circuitry
wherein the laser radiation device comprises:
a laser head configured to oscillate the laser light; and
an optical system configured to branch the laser light from the laser head, and
the circuitry is configured to control the laser head and the optical system to:
radiate multiple branch laser lights, which are obtained by branching the laser light, in a pulse shape to an outer peripheral region of the substrate, and
radiate single laser light, which is obtained by not branching the laser light, in a pulse shape to a central region diametrically inside the outer peripheral region.

9. The substrate processing apparatus of claim 8, further comprising:
a rotator configured to rotate the substrate holder; and
a laser scanner configured to scan the single laser light,
wherein the circuitry is configured to:
control the laser radiation device to radiate, to the outer peripheral region, the multiple branch laser lights while causing the rotator to rotate the substrate, and
control the laser radiation device to radiate, to the central region, the single laser light while causing the laser scanner to scan the single laser light in a state that rotation of the substrate is stopped.

10. The substrate processing apparatus of claim 9, further comprising:
a fixed lens configured to radiate the branch laser lights; and
a scanning lens configured to radiate the single laser light while scanning the single laser light.

11. The substrate processing apparatus of claim 8,
wherein the optical system comprises:
a first optical path in which the laser light is branched; and
a second optical path in which the laser light is not branched, and
the circuitry is configured to control the laser head and the optical system to:
control the laser radiation device to radiate, to the outer peripheral region, the multiple branch laser lights by allowing the laser light to pass through the first optical path, and
control the laser radiation device to radiate, to the central region, the single laser light by allowing the laser light to pass through the second optical path.

12. The substrate processing apparatus of claim 11,
wherein the optical system further comprises:
a polarization adjuster configured to adjust polarization of the laser light:
a polarization separator configured to transmit or reflect polarized light adjusted by the polarization adjuster:
a branch generator configured to branch the polarized light transmitted by the polarization separator: and
a polarization synthesizer configured to reflect the polarized light reflected by the polarization separator or transmit the polarized light branched by the branch generator

13. The substrate processing apparatus of claim 11,
wherein the optical system further comprises:
a branch generator configured to branch the laser light:
a first mirror configured to be moved forward and backward and positioned at an upstream side of the branch generator: and
a second mirror configured to be moved forward and backward and positioned at a downstream side of the branch generator.

14. The substrate processing apparatus of claim 8,
wherein the optical system comprises a spatial phase modulator of the laser light, and
the circuitry is configured to control a phase of the laser light in the spatial phase modulator to control the branching of the laser light.

15. The substrate processing apparatus of claim 12, wherein
in the first optical path, the polarized light is transmitted by the polarization separator, branched by the branch generator, and transmitted by the polarization synthesizer, and
in the second optical path, the polarized light is reflected by the polarization separator and reflected by the polarization synthesizer.

16. The substrate processing apparatus of claim 13, wherein
in the first optical path, the laser light is branched by the branch generator in a state that the first mirror and the second mirror are in a retreated position and the laser light is not reflected from the first mirror or the second mirror, and
in the second optical path, the laser light is reflected by the first mirror and reflected by the second mirror in a state that the first mirror and the second mirror are in an advanced position.

17. The substrate processing apparatus of claim 14, wherein the spatial phase modulator includes at least one deformable mirror.

18. The substrate processing apparatus of claim 17, wherein the spatial phase modulator includes a plurality of deformable mirrors, and
the circuitry is configured to individually control the plurality of deformable mirrors to control branching of the laser light.

19. The substrate processing apparatus of claim 14, further comprising:
a fixed lens configured to radiate the branch laser lights; and
a scanning lens configured to radiate the single laser light while scanning the single laser.

20. The substrate processing apparatus of claim 8, further comprising a linear motor,
wherein
the substrate holder is a chuck,
the substrate holder is supported on a slider table, and
the slider table is movable along a rail provided on a base.
